(19) United States
(12) Patent Application Publication
(10) Pub. No.: US 2007/0090758 A1
(43) Pub. Date: Apr. 26, 2007

(54) Electroluminescent panel

(76) Inventors: David M. Kwasny, Corvallis, OR (US); Marshall Field, Corvallis, OR (US); Sterling Chaffins, Albany, OR (US); Terry M. Lambright, Corvallis, OR (US); Douglas R. Houck, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/256,323

(22) Filed: Oct. 21, 2005

(51) Int. Cl. H01J 1/62

(52) U.S. Cl. 313/509

(57) ABSTRACT

An electroluminescent panel includes a partial electroluminescent panel base and a deactivatable conductive layer next to the partial electroluminescent panel base. The deactivatable conductive layer is selectively deactivated to define one or more electrically isolated conductive regions within the deactivatable conductive layer.

### BACKGROUND

An electroluminescent (EL) panel includes a layer of electroluminescent phosphor and a dielectric sandwiched between front and rear electrodes. At least one of these electrodes is transparent. On application of a voltage, the electroluminescent phosphor emits light. One or both of the electrodes, usually the rear electrode, may be divided into a number of different regions, so that corresponding regions of the EL panel can be selectively and independently lit. Typically, creating the different regions of these electrodes is accomplished by a screen-printing process. However, the screen-printing process is cost effective only for large production runs. That is, where just a small number of EL panels are desired to be made with particular independently and selectively lit regions, the screen-printing process can be cost prohibitive.

### BRIEF DESCRIPTION OF THE DRAWINGS

The drawings referenced herein form a part of the specification. Features shown in the drawing are meant as illustrative of only some embodiments of the invention, and not of all embodiments of the invention.

FIG. 1 is a diagram of cross-sectional side view of an electroluminescent panel having a deactivatable conductive layer, according to an embodiment of the invention.

FIG. 2 is a diagram of a cross-sectional top view of the electroluminescent panel of FIG. 1 in which the deactivatable conductive layer is specifically shown or exposed, according to an embodiment of the invention.

FIG. 3 is a diagram of a cross-sectional side view of the electroluminescent panel of FIGS. 1 and 2 in which a transparent front conductor is present, according to an embodiment of the invention.

FIG. 4 is a diagram of a top view of an example or representative interdigitated conductive layer that can be used in the electroluminescent panel of FIGS. 1 and 2, according to an embodiment of the invention.

FIG. 5 is a diagram of a cross-sectional side view of the electroluminescent panel of FIGS. 1 and 2 in which an interdigitated conductive layer is present, according to an embodiment of the invention.

FIG. 6 is a diagram of a top view of an example or representative interdigitated conductive layer that has been patterned into more than one combined anode-and-cathode region, according to an embodiment of the invention.

FIG. 7 is a diagram of a cross-sectional side view of an electroluminescent panel in which the interdigitated conductive layer of FIG. 6 is present, according to an embodiment of the invention.

FIG. 8 is a flowchart of a method that can be performed in relation to the electroluminescent panel of FIGS. 1, 2, 3, and 5, according to an embodiment of the invention.

FIG. 9 is a flowchart of a method that can be performed in relation to the electroluminescent panel of FIG. 7, according to an embodiment of the invention.

### DETAILED DESCRIPTION OF THE DRAWINGS

In the following detailed description of exemplary embodiments of the invention, reference is made to the accompanying drawings that form a part thereof, and in which is shown by way of illustration specific exemplary embodiments in which the invention may be practiced. These embodiments are described in sufficient detail to enable those skilled in the art to practice the invention. Other embodiments may be utilized, and logical, mechanical, electrical, electro-optical, software/firmware and other changes may be made without departing from the spirit or scope of the present invention. The following detailed description is, therefore, not to be taken in a limiting sense, and the scope of the present invention is defined only by the appended claims.

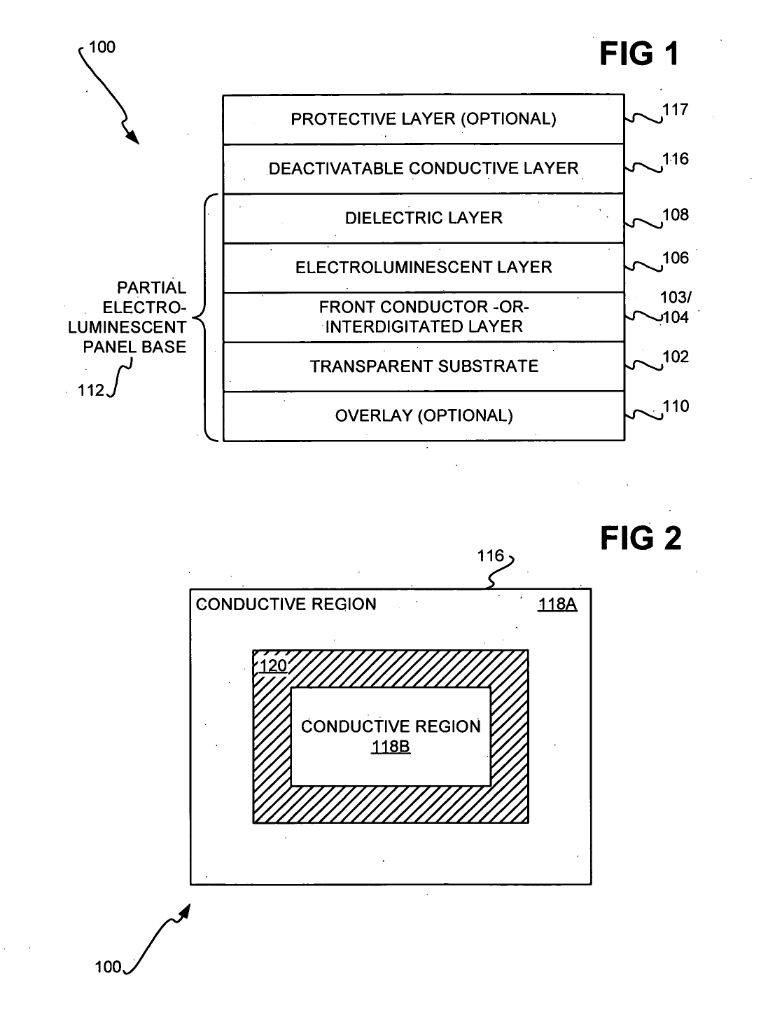

FIG. 1 shows a cross-sectional side view of an electroluminescent (EL) panel 100, according to an embodiment of the invention. The EL panel 100 includes a transparent substrate 102. The EL panel 100 also includes a transparent front conductor 103 or an interdigitated conductive layer 104 next to or over the transparent substrate 102, where the terminology conductor/layer 103/104 refers to the presence of either the transparent front conductor 103 or the interdigitated conductive layer 104. The EL panel 100 further includes an electroluminescent layer 106 situated next to or over the conductor/layer 103/104, and a dielectric layer 108 situated next to or over the electroluminescent layer 106. The substrate 102, the conductor/layer 103/104, the electroluminescent layer 106, and the dielectric layer 108 may together be referred to as a partial EL panel base 112 in one embodiment. The EL panel 100 also includes a deactivatable conductive layer 116 next to or over the dielectric layer 108 and thus next to or over the partial EL panel base 112, and optionally a protective layer 117 next to or over the deactivatable conductive layer 116. The EL panel 100 may further optionally include an overlay 110, which may be part of the partial EL panel base 112.

The EL panel 100 is depicted in FIG. 1 upside-down to indicate how the various layers arid components of the EL panel 100 are typically fabricated. In actual use, the transparent substrate 102 is oriented so that it is positioned towards the front, or top. As a result, light from the electroluminescent layer 106 can emit therethrough, and the dielectric layer 108 is positioned towards the back, or bottom.

The transparent substrate 102 may be polyethylene terephthalate (PET), another type of clear plastic, or another type of transparent substrate material. The substrate 102 is transparent in the sense that it is at least partially or substantially transparent, and/or at least partially or substantially allows light to transmit therethrough. Description regarding the transparent front conductor 103 and the interdigitated conductive layer 104 is provided later in the detailed description. The electroluminescent layer 106 may be inorganic or organic phosphor. The dielectric layer 108 may be barium titanate powder in a polyurethane binder, or another type of dielectric.

The overlay 110 may be a plastic or another type of overlay, and may have graphics printed thereon, such as for marketing, advertising, and/or other purposes. Alternatively, the overlay 110 may be an ink-receptive layer that is receptive to artwork or other graphics inkjet-printed thereon. Where the overlay 110 is not present, the artwork or other graphics may be directly inkjet-printed on the transparent substrate 102.

The deactivatable conductive layer 116 as applied to the dielectric layer 108 is initially wholly conductive. However, where the conductive layer 116 is deactivated, the conductive layer 116 becomes nonconductive. More particularly, the deactivatable conductive layer 116 remains conductive at locations thereof that have not been deactivated, and becomes nonconductive at locations thereof that have been deactivated. In one embodiment, the deactivatable conductive layer 116 is an optical beam-deactivatable conductive layer, such as a laser-deactivatable conductive layer. In such an embodiment, the layer 116 becomes nonconductive where exposed to an optical beam having a wavelength to which the layer 116 is sensitive, and remains conductive where the layer 116 is not exposed to the optical beam.

An example of such a laser-deactivatable conductive layer is a solution of conductive polymer-composite, with an added antenna material of 1-2% of the total solution that is sensitive to a particular wavelength of the electromagnetic spectrum. The conductive polymer composite may be a dip-coated film of polypropylene and carbon black, where the polypropylene is 64% of the total solution, and the carbon black is 34% of the total solution. The antenna material may be an infrared (IR) antenna material, such as the near-infrared dye known as ADS780pp, and available from American Dye Source, Inc., of Toronto, Canada, and which is sensitive to a wavelength of light of 780 nanometers (nm). The solvent of the solution may be o-xylenes, and makes up 2% of the total solution. More generally, the laser-deactivatable conductive layer in one embodiment is a solution that includes a conductive material, an insulating host which can be either thermally or photochemically removed, and an antenna that transfers light energy as heat to the surrounding environment. The solution is applied to the dielectric layer 108, and upon evaporation of the solvent, the deactivatable conductive layer 116 results in which the layer 116 is initially conductive. Multiple passes of the optical beam or laser having a wavelength of light of 780 nm may be needed to render the layer 116 nonconductive.

FIG. 2 shows a cross-sectional top view of the EL panel 100, not including the protective layer 117, according to an embodiment of the invention. Thus, the deactivatable conductive layer 116 is depicted in the cross-sectional top view of the EL panel 100 in FIG. 2. The deactivatable conductive layer 116 is selectively deactivated to define electrically isolated conductive regions 118A and 118B, collectively referred to as the electrically isolated conductive regions 118. Specifically, the deactivatable conductive layer 116 is deactivated at locations within the region 120, such that the region 120 becomes a nonconductive region of the layer 116, which electrically isolates the conductive regions 118 from one another. While there are two conductive regions 118 and one nonconductive region 120 in the embodiment of FIG. 2, in other embodiments there may be more or less than two conductive regions 118, and/or more than one nonconductive region 120.

EL panels like the EL panel 100 may be manufactured in large runs, or in bulk, where the activatable conductive layers thereof are not initially activated. To construct a particular EL panel, such as the EL panel 100, having particular conductive regions, such as the conductive regions 118, the activatable conductive layer of a given manufactured-in-bulk EL panel is selectively deactivated to define desired conductive regions. That is, the EL panels themselves may be fabricated in a mass-produced, cost-effective manner, and can subsequently be customized by defining the desired conductive regions via selectively deactivating the deactivatable conductive layer. Additionally, customized graphics may be applied to the EL panels via inkjet-printing on the overlays or on the transparent substrates of the panels, which may be aligned to the conductive regions that have been defined.

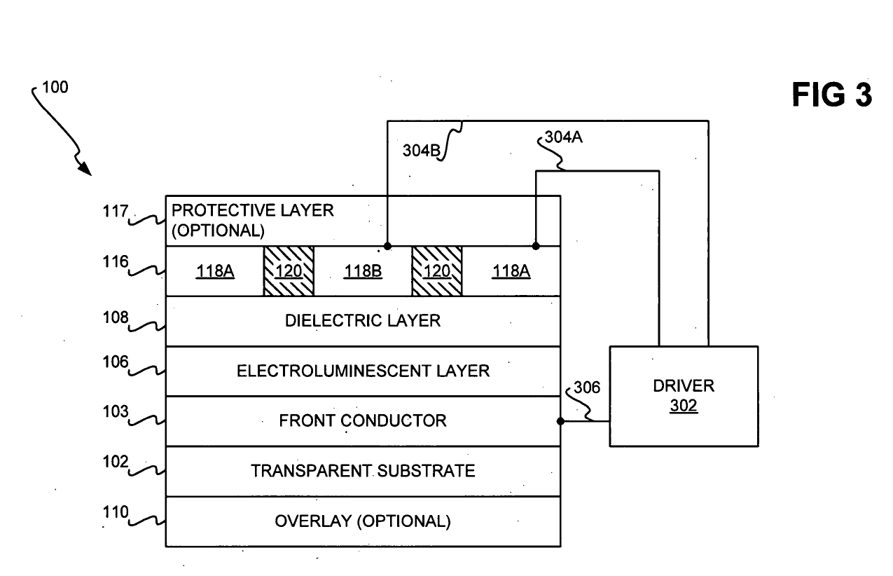

FIG. 3 shows a cross-sectional side view of the EL panel 100 of FIG. 2 as including the transparent front conductor 103 instead of the interdigitated conductive layer 104, according to an embodiment of the invention. The transparent front conductor 103 may be indium tin oxide (ITO), antimony tin oxide (ATO), or another type of transparent conductive material. The conductor 103 is transparent in the sense that it is at least partially or substantially transparent, and/or at least partially or substantially allows light to transmit therethrough. The conductor 103 is a front conductor because in actual use, the conductor 103 is oriented so that it is positioned towards the front, or top, so that light from the electroluminescent layer 106 can emit therethrough, and the deactivatable conductive layer 116 is positioned towards the back, or bottom.

In the embodiment of FIG. 3, the transparent front conductor 103 serves as a front electrode, while each of the conductive regions 118 of the, deactivatable conductive layer 116 serves as an independent rear electrode. The front electrode may be the anode, for instance, whereas the independent rear electrodes may each be a cathode, or the front electrode may be the cathode and the independent rear electrodes may each be an anode. Electrical connects 304A and 304B are attached between the conductive regions 118A and 118B and an electrical driver 302, which includes or is connected to a voltage source, such as a battery or a wall outlet. Another electrical connect 306 is attached between the transparent front conductor 103 and the driver 302.

Applying a voltage between the conductive region 118A and the transparent front conductor 103 energizes a capacitor formed by the region 118A acting as one capacitive plate, the front conductor 103 acting as another capacitor plate, the electroluminescent layer 106, and the dielectric layer 108. As a result, substantially just the portion of the electroluminescent layer 106 correspondingly underneath the conductive region 118A emits light. This is further accomplished by the driver 302 driving a voltage between the electrical connect 304A and the electrical connect 306.

Similarly, applying a voltage between the conductive region 118B and the transparent front conductor 103 energizes a capacitor formed by the region 118B acting as one capacitive plate, the front conductor 103 acting as another capacitive plate, the electroluminescent layer 106, and the dielectric layer 108.

As a result, substantially just the portion of the electroluminescent layer 106 corresponding underneath the conductive region 118B emits light. This is further accomplished by the driver 302 driving a voltage between the electrical connect 304B and the electrical connect 306.

Therefore, the conductive regions 118 are defined in accordance with a number, and shape, of regions of the EL panel 100 that are desired to be selectively and independently illuminated. In FIG. 3, there are two such conductive regions, or rear electrode regions, for illustrative and descriptive convenience. However, there can be any number of different conductive regions in any number of different shapes and sizes. Each of the conductive regions 118 corresponds to a region of the EL panel 100 of FIG. 3 as a whole that can be selectively and independently illuminated.

It is noted that in the embodiment of FIG. 3, driving a voltage between the electrical connects 304A and 306 is independent of driving a voltage between the electrical connects 304B and 306. Therefore, either a voltage may be driven between the connects 304A and 306, between the connects 304B and 306, or between both the connects 304A and 304B and the connect 306. Thus, either a region of the EL panel 100 corresponding to the conductive region 118A can be illuminated, a region of the EL panel 100 corresponding to the conductive region 118B can be illuminated, or regions of the EL panel 100 corresponding to both the conductive regions 118 can be illuminated.

In one embodiment, the overlay 110 may further be divided into overlay regions corresponding to the conductive regions 118. Therefore, the overlay 110 may be said to be aligned to the deactivatable conductive layer 116, so that when the conductive region 118A is energized, a corresponding overlay region is illuminated, and when the conductive region 118B is energized, a different corresponding overlay region is illuminated. Where the overlay 110 is not present, but where graphics are inkjet-printed directly on the transparent substrate 102, the transparent substrate 102 may alternatively be said to be divided into regions corresponding to the conductive regions 118.

It is noted that the optional protective layer 117, where present, may be applied to the EL panel 100 vis-à-vis the electrical connects 304A and 304B in one of two ways. First, the electrical connects 304A and 304B may be attached to the conductive regions 118, and then the protective layer 117 applied thereover. Second, the protective layer 117 may be initially applied to the conductive regions 118, and then the protective layer 117 cut or pierced to partially expose the conductive regions 18 so that the electrical connects 304A and 304B may be attached to the conductive regions 118 where exposed.

Furthermore, in FIG. 3, the transparent front conductor 103 is depicted such that the layers 106, 108, 116, and 117 extend completely over the front conductor 103, such that the electrical connect 306 is depicted as being attached to the side of the conductor 103. In some embodiments, however, the layers 106,108, 116, and 117 may not completely extend over the front conductor 103, such that the electrical connect 306 can be attached to the bottom surface of the conductor 103, where the bottom surface of the conductor 103 is the surface next to the electroluminescent layer 106. Additionally or alternatively, the front conductor 103 may include a front busbar, as can be appreciated by those of ordinary skill within the art, to which the electrical connect 306 is attached.

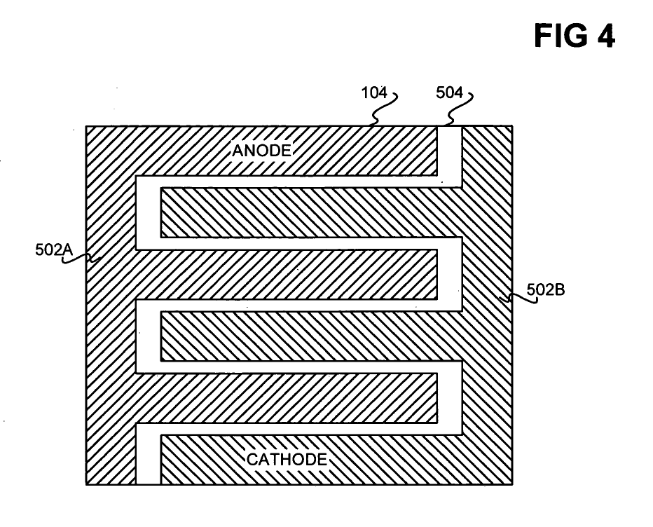

The EL panel 100 of FIGS. 1 and 2 has been described as to the embodiment of FIG. 3 in which there is a transparent front conductor 103, and in which there is not an interdigitated conductive layer 104. Alternatively, an interdigitated conductive layer 104 can be employed in relation to the EL panel 100 of FIGS. 1 and 2. FIG. 4 shows top view of a representative and example interdigitated conductive layer 104, according to an embodiment of the invention. The interdigitated conductive layer 104 includes an anode conductive region 502A and a cathode conductive region 502B that are electrically isolated from one another via a nonconductive region 504. Thus, the anode region 502A and the cathode region 502B are interdigitated with one another. It is noted that embodiments of the invention can be employed both with alternating current (AC) electrical power and direct current (DC) electrical power. In both situations, electricity typically flows from an anode to a cathode.

The interdigitated conductive layer 104 may be fabricated in a number of different ways. For instance, a deactivatable conductive layer, similar to the deactivated conductive layer 116, may form the interdigitated conductive layer 104. The interdigitated conductive layer 104 is thus initially wholly conductive, and is deactivated at locations within the region 504 to render the region 504 nonconductive and to define and electrically isolate the anode conductive region 502A and cathode conductive region 502B, which are both initially and remain conductive.

As another example, an activatable conductive layer may instead form the interdigitated conductive layer 104. An activatable conductive layer is a layer that is initially wholly nonconductive, and that is selectively activated to define the anode conductive region 502A and the cathode conductive region 502B. The interdigitated conductive layer 104 is thus activated at locations within the regions 502A and 502B to render these regions 502A and 502B conductive, while the region 504 remains nonconductive.

In one embodiment, such an activatable conductive layer may be an optical-beam activated conductive layer, such as a laser-activated conductive layer. In such an embodiment, the interdigitated conductive layer 104 becomes conductive where exposed to an optical beam having a wavelength to which the layer 104 is sensitive, and remains nonconductive where the layer 104 is not exposed to the optical beam. For instance, such an optically activated conductive layer is described in the previously filed, copending, and coassigned patent application entitled “Conductive Patterning,” filed on Jun. 1, 2005, and assigned Ser. No. 11/142,699. The wavelength of light to which such an optically activated conductive layer is sensitive may be 780 nanometers (nm). The layer 104 may be applied to or over the transparent substrate 102 as a paste, which then hardens into the layer 104. The paste may be a silver paste in one embodiment, and may change color at locations at which it has been activated and thus is conductive.

As another example, the interdigitated conductive layer 104 may be formed by inkjet-printing conductive ink on the transparent substrate 102. For instance, the previously filed, copending, and coassigned patent application entitled “Electroluminescent Panel with Inkjet-Printed Electrode Regions,” filed on May 7, 2005, and assigned Ser. No. 11/124,249, describes the utilization of such a conductive ink to form electrode regions of an EL panel. Here, conductive ink is instead inkjet-printed to define or form the interdigitated conductive layer 104.

It is noted that the terminology “inkjet-printing using conductive ink” encompasses such inkjet printing where more than one conductive ink is employed. Furthermore, the terminology “conductive ink” encompasses ink that is not immediately conductive upon inkjet-printing, but becomes conductive after further actions-are performed. For instance, some inks become conductive upon being thermally or otherwise cured. Therefore, inkjet-printing using conductive ink encompasses performing whatever actions are needed to render the ink conductive. For example, a polymer-capped monomodal silver nano-particle ink is available from Cabot Corp. that is applied by inkjet-printing, and subsequently is subjected to a low-temperature sintering to remove the caps on the particles, which increases the surface contact of the particles and increases their conductivity to render the ink conductive.

It is noted that the interdigitated conductive layer depicted in FIG. 4 is one example of a single layer within which pairs of anodes and cathodes are in close proximity to one another. Other embodiments of the invention can utilize other topologies of pairs of anodes and cathodes in close proximity to one another within a single layer. As just one example, parallel spiral lines can be employed to implement pairs of anodes and cathodes within a single layer. For instance, two parallel spiral lines may form the anode and the cathode of an anode and cathode pair, and several such groupings of parallel spiral lines may be achieved within the same layer. Either the front conductor, the rear electrode, or both the front conductor and the rear electrode can be implemented as a layer having one or more pairs of anodes and cathodes in close proximity to one another.

Thus, in various embodiments of the invention particularly described herein, the front conductor and/or the rear electrode are particularly described as being deactivatable or activatable, and/or as having one or more pairs of anodes and cathodes within the same layer. However, other embodiments of the invention are directed to all possible combinations of the front conductor and/or the rear electrode being activatable or deactivatable, and/or having one or more pairs of anodes and cathodes within the same layer. Furthermore, in embodiments of the invention that are described herein in relation to a deactivatable conductive layer, such embodiments can also be implemented in relation to an activatable conductive layer.

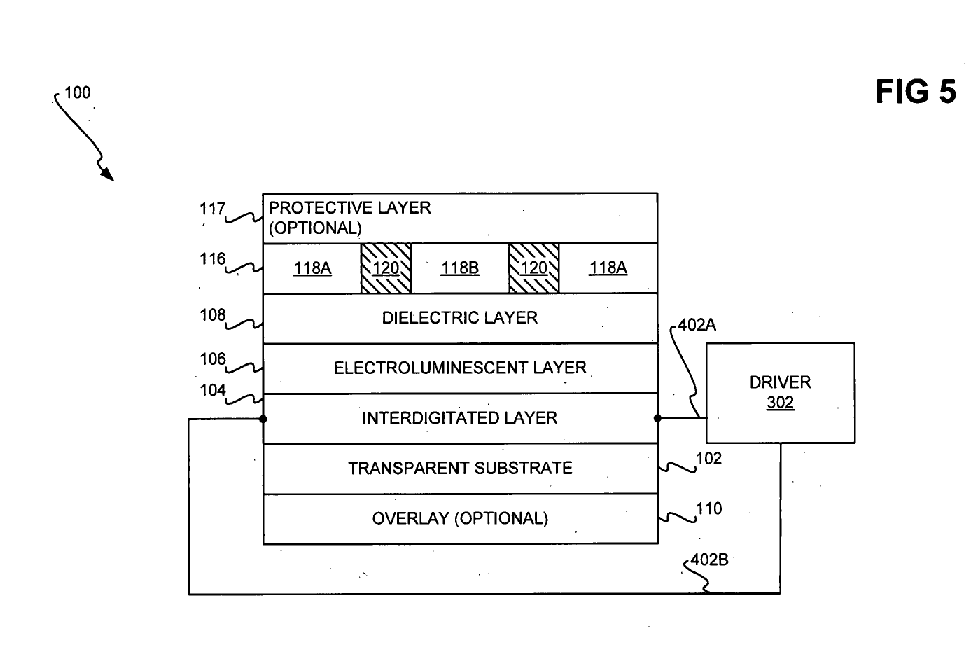

FIG. 5 shows a cross-sectional side view of the EL panel 100 of FIG. 2 as including the interdigitated conductive layer 104 instead of the transparent front conductor 103, according to an embodiment of the invention. The interdigitated conductive layer 104 may be that which has been exemplarily described in relation to FIG. 4. The conductive layer 104 may further be transparent, in the sense that it is at least partially or substantially transparent, and/or at least partially or substantially allows light to transmit therethrough. The conductive layer 104 may further be a front conductive layer because in actual use, the layer 104 is oriented so that it is positioned towards the front, or top, so that light from the electroluminescent layer 106 can emit therethrough, and the deactivatable conductive layer 116 is positioned towards the back, or bottom.

In the embodiment of FIG. 5, the conductive regions 118 of the deactivatable conductive layer 116 serve as a bridge conductor for the anode and the cathode regions 502A and 502B of the interdigitated conductive layer 104, where the anode and the cathode regions 502A and 502B are not specifically shown in FIG. 5, but rather are specifically depicted in FIG. 4. Electrical connects 402A and 402B are thus attached between the anode and the cathode regions 502A and 502B and the electrical driver 302, which includes or is connected to a voltage source, such as a battery or a wall outlet. Therefore, in the embodiment of FIG. 5, no electrical connects are attached to the conductive regions 118 of the deactivatable conductive layer 116.

Applying a voltage between the anode and the cathode regions 502A and 502B of the interdigitated conductive layer 104 energizes a capacitor formed between the anode and the cathode regions 502A and 502B acting as the capacitive plates, and also including the conductive regions 118 of the deactivatable conductive layer 116, the electroluminescent layer 106, and the dielectric layer 108. That is, the electrical path of the capacitor formed is from the anode region 502A, through the electroluminescent layer 106 and the dielectric layer 108 to the conductive regions 118, and back through the dielectric layer 108 and the electroluminescent layer 106 to the cathode region 502B, or alternatively starting at the cathode region 502B and ending at the anode region 502A. As a result, substantially just the portion of the electroluminescent layer 106 correspondingly underneath the conductive regions 118 emits light. This is further accomplished by the driver 302 driving a voltage between the electrical connects 402A and 402B.

Therefore, the conductive regions 118 are defined in accordance with a number, and shape, of regions of the EL panel 100 that are desired to be illuminated at the same time. In FIG. 5, there are two such conductive regions, or bridge conductors, for illustrative and descriptive convenience. However, there can be any number of different conductive regions in any number of different shapes and sizes. The conductive regions 118 correspond to the regions of the EL panel 100 of FIG. 5 as a whole that can be illuminated at the same time.

The embodiment of FIG. 5 therefore differs from the embodiment of FIG. 3 in that in the embodiment of FIG. 3 the conductive regions 118 may be independently and selectively energized, or powered, to independently and selectively illuminate corresponding regions of the EL panel 100. By comparison, in the embodiment of FIG. 5, the conductive regions 118 are energized or powered at the same time, to illuminate corresponding regions of the EL panel 100 at the same time. In FIG. 3, the conductive regions 118 are rear electrode regions, and are either independent cathodes or anodes. In FIG. 5, the conductive regions 118 are bridge conductive regions, and are not cathodes or anodes. Thus, in the embodiment of FIG. 5, driving a voltage between the electrical connects 402A and 402B results in the illumination of regions of the EL panel 100 corresponding to all the conductive regions 118.

In one embodiment, the overlay 110 may further be divided into overlay regions corresponding to the conductive regions 118 of the deactivatable conductive layer 116. Therefore, the overlay 110 may be said to be aligned to the deactivatable conductive layer 116, so that when the conductive regions 118 are energized, corresponding overlay regions are illuminated. Where the overlay 110 is not present, but where graphics are inkjet-printed directly on the transparent substrate 102, the transparent substrate 102 may alternatively be said to be divided into regions corresponding to the conductive regions 118.

It is noted that in FIG. 5, the interdigitated conductive layer 104 is depicted such that the layers 106, 108, 116, and 117 extended completely thereover, such that the electrical connects 402A and 402B are depicted as being attached to sides of the interdigitated conductive layer 104. In some embodiments, however, the layers 106,108,116, and 117 may not completely extend over the interdigitated conductive layer 104, such that the electrical connects 402A and 402B can be attached to the bottom surface of the layer 104, where this bottom surface is the surface next to the electroluminescent layer 106. Additionally or alternatively, the interdigitated conductive layer 104 may include front busbars for both the anode conductive region and the cathode conductive region of the interdigitated conductive layer 104, as can be appreciated by those of ordinary skill within the art, to which the electrical connects 402A and 402B are attached.

It is also noted that the embodiment of FIG. 5 has been described such that the interdigitated conductive layer 104 is located towards the front of the EL panel 100, next to the transparent substrate 102, whereas the deactivatable conductive layer 116 is located towards the rear of the EL panel 100, next to the dielectric layer 108. In another embodiment, the locations of the layers 104 and 116 may be switched, such that the deactivatable conductive layer 116 is located towards the front of the EL panel 100, next to the transparent substrate 102, and the interdigitated conductive layer 104 is located towards the rear of the EL panel, next to the dielectric layer 108. The electrical connects 402A and 402B thus can extend through or under the protective layer 117. The protective layer 117 may be applied first, and cut or pierced to expose the anode and the cathode regions 502A and 502B to which the electrical connects 402A and 402B are then attached. The protective layer 117 may also be applied after the electrical connects 402A and 402B have been attached to the anode and the cathode regions 502A and 502B.

In this embodiment, the, interdigitated conductive layer 104 does not need to be transparent, since it is located towards the rear of the EL panel 100. However, the deactivatable conductive layer 116 in this alternative embodiment is desirably transparent, since it is located towards the front of the EL panel 100. The deactivatable conductive layer 116 is transparent in this embodiment in the sense that it is at least partially or substantially transparent, and/or at least partially or substantially allows light to transmit therethrough. Such a deactivatable conductive layer that is transparent may be an organic conductor, such as PEDOT (polyethylenedioxythiophene), Orgacon, indium tin oxide, or antimony tin oxide, with an added infrared dye that is sensitive to a wavelength to which the layer is selectively exposed to selectively deactivate the layer and render it selectively nonconductive.

Embodiments of the invention have been described thus far in which the deactivatable conductive layer 116 is selectively deactivated to define electrically isolated conductive regions 118 within the layer 116. As such, in the embodiments of FIGS. 4 and 5 that have been described where the interdigitated conductive layer 104 is present, the interdigitated conductive layer 104 includes one anode region 502A and one cathode region 502B. Stated another way, the interdigitated conductive layer 104 includes one combined anode-and-cathode region, made up of the anode region 502A and the cathode region 502B. That is, the interdigitated conductive layer 104 may be considered as being unpatterned since it includes just one combined anode-and-cathode region.

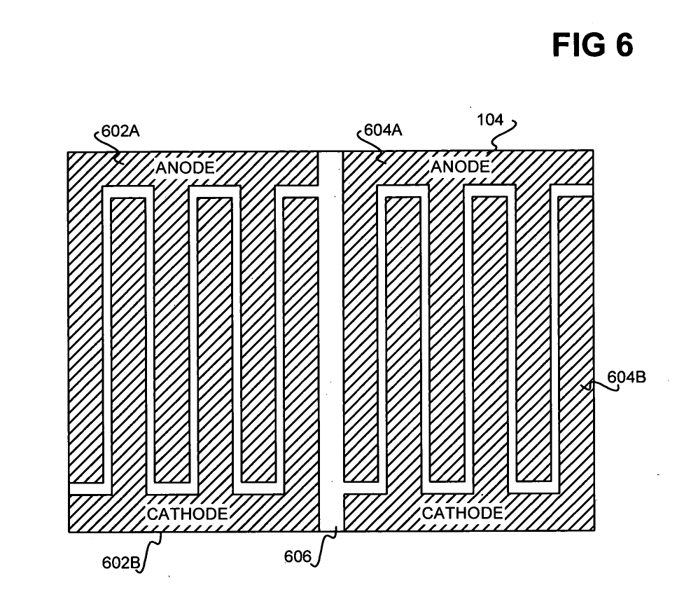

By comparison, FIG. 6 shows a top view of a representative and example of the interdigitated conductive layer 104 having a number of combined anode-and-cathode regions 602 and 604, according to a different embodiment of the invention. The combined anode-and-cathode region 602 includes an anode conductive region 602A and a cathode-conductive region 602B that are electrically isolated from one another via a nonconductive region 606. The anode region 602A and the cathode region 602B are interdigitated with one another. The combined anode-and-cathode region 604 includes an anode conductive region 604A and a cathode conductive region 604B that are also electrically isolated from one another via the nonconductive region 606. The anode region 604A and cathode region 604B are also interdigitated with one another. The nonconductive region 606 further electrically isolates the combined anode-and-cathode region 602 from the combined anode-and-cathode region 604. Because there is more than one combined anode-and-cathode region within the layer 104 in FIG. 6, the layer 104 is said to be patterned.

The interdigitated conductive layer 104 of FIG. 6 may be fabricated in a number of different ways. For instance, the deactivatable conductive layer 116 of FIG. 1 may implement the interdigitated conductive layer 104 of FIG. 6 in one embodiment. The interdigitated conductive layer 104 is thus initially wholly conductive. The layer 104 is then deactivated at locations within the region 606 to render the region 606 nonconductive and to define and electrically isolate the combined anode-and-cathode regions 602 and 604, including defining and electrically isolating the constituent anode regions 602A and 604A and the constituent cathode regions 602B and 604B of the regions 602 and 604, which are initially and remain conductive.

As another example, an activatable conductive layer, such as an optical beam-activated conductive layer, may instead form the interdigitated conductive layer 104 of FIG. 6. Such an activatable conductive layer is initially wholly nonconductive, and is selectively activated to define the anode regions 602A and 604A and the cathode regions 602B and 604B, such that the combined anode-and-cathode regions 602 and 604 are defined. The interdigitated conductive layer 104 is thus activated at locations within the regions 602A, 604A, 602B, and 604B to render them conductive, while the region 606 remains nonconductive. As a final example, the interdigitated conductive layer 104 of FIG. 6 may be formed by inkjet-printing conductive ink on the dielectric layer 108 to define the interdigitated conductive layer 104.

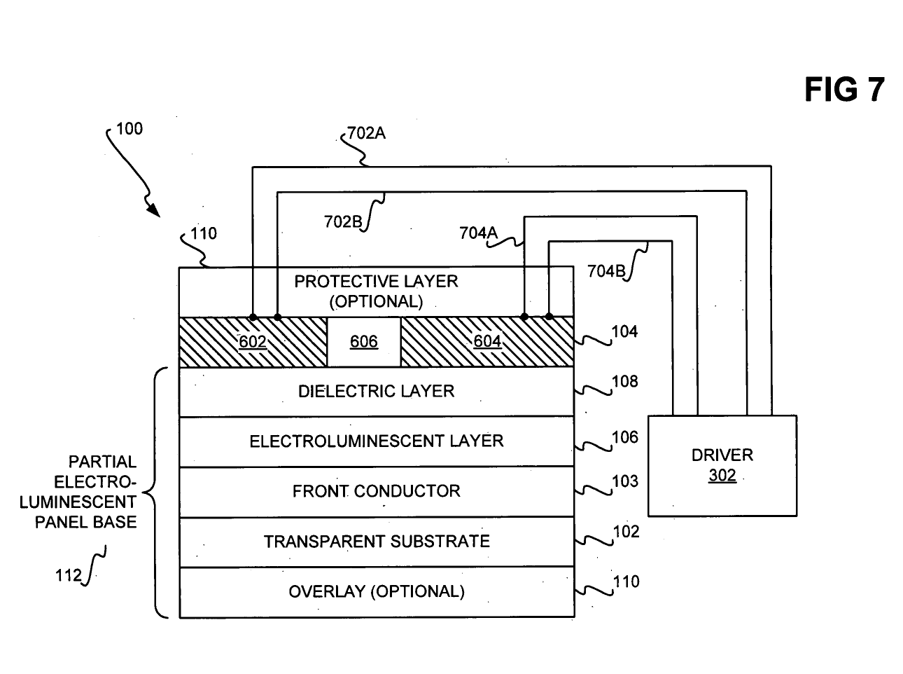

FIG. 7 shows a cross-sectional side view of the EL panel 100 as including the interdigitated conductive layer 104 that includes a number of combined anode-and-cathode regions 602 and 604, according to an embodiment of the invention. The EL panel 100 specifically includes the transparent substrate 102, the front conductor 103 next to or over the transparent substrate 102, the electroluminescent layer 106 next to or over the conductor 103, and the dielectric layer 108 next to or over the electroluminescent layer 106. The substrate 102, the conductor 103, and the layers 106 and 108 may be referred to as the partial EL panel base 112 in one embodiment. The EL panel 100, and the partial EL panel base 112 thereof, may further include an optional overlay 110. The interdigitated conductive layer 104 is located over or next to the dielectric layer 108, and an optional protective layer 110 is situated over or next to the interdigitated conductive layer 104.

As in FIG. 1, the EL panel 100 is depicted in FIG. 7 upside-down to indicate how the various layers and components of the EL panel 100 are typically fabricated. In actual use, the transparent substrate 102 is oriented so that it is positioned towards the front, or top. As a result, light from the electroluminescent layer 106 can emit therethrough, and the dielectric layer 108 is positioned towards the back, or bottom.

In the embodiment of FIG. 7, the front conductor 103 serves as a bridge conductor for the anode and the cathode regions of each of the combined anode-and-cathode regions 602 and 604. The anode regions 602A and 604A of the region 602 and the cathode regions 602B and 604B of the region 604 are not specifically shown in FIG. 7 Electrical connects 702A and 702B are attached between the anode and the cathode regions 602A and 602B of the region 602 and the electrical driver 302, and electrical connects 704A and 704B are attached between the anode and the cathode regions 604A and 604B of the region 604 and the electrical driver 302.

Applying a voltage between the anode and cathode regions of the combined-anode-and-cathode region 602 energizes a capacitor formed between the anode and cathode regions 602A and 602B acting as the capacitive plates, and also including the front conductor 103, the electroluminescent layer 106, and the dielectric layer 108. That is, the electrical path of the capacitor formed is from the anode region 602A, through the dielectric layer 108 and the electroluminescent layer 106 to the front conductor 103, and back through the electroluminescent layer 106 and the dielectric layer 108 to the cathode region 602B, or alternatively starting at the cathode region 602B and ending at the anode region 602A. As a result, substantially just the portion of the electroluminescent layer 106 correspondingly underneath the combined anode-and-cathode region 602 emits light. This is further accomplished by the driver 302 driving a voltage between the electrical connects 702A and 702B.

Similarly, applying a voltage between the anode and cathode regions of the combined anode-and-cathode region 604 energizes a capacitor formed between the anode and cathode regions 604A and 604B acting as the capacitive plates, and also including the front conductor 103, the electroluminescent layer 106, and the dielectric layer 108. That is, the electrical path of the capacitor formed is from the anode region 604A, through the dielectric layer 108 and the electroluminescent layer 106 to the front conductor 103, and back through the electroluminescent layer 106 and the dielectric layer 108 to the cathode region 604B, or alternatively starting at the cathode region 604B and ending at the anode region 604A. As a result, substantially just the portion of the electroluminescent layer 106 correspondingly underneath the combined anode-and-cathode region 604 emits light. This is further accomplished by the driver 302 driving a voltage between the electrical connects 704A and 704B. Therefore, the combined anode-and-cathode regions 604 are defined in accordance with a number, and shape, of regions of the EL panel 100 that are desired to be selectively and independently illuminated. In FIG. 7, there are two such regions, for illustrative and descriptive convenience. However, there can be any number of different combined anode-and-cathode regions in any number of different shapes and sizes. Each of the regions 604 corresponds to a region of the EL panel 100 of FIG. 7 as a whole that can be selectively and independently illuminated.

It is noted that in the embodiment of FIG. 7, driving a voltage between the electrical connects 702A and 702B is independent of driving a voltage between the electrical connects 704A and 704B. Therefore, either a voltage may be driven between the connects 702A and 702B, between the connects 704A and 704B, or both between the connects 702A and 702B and between the connects 704A and 704B. Thus, either a region of the EL 100 panel corresponding to the region 602 can be illuminated, a region of the EL panel 100 corresponding to the region 604 can be illuminated, or regions of the EL panel 100 corresponding to both the regions 602 and 604 can be illuminated.

In one embodiment, the overlay 110 may further be divided into overlay regions corresponding to the combined anode-and-cathode regions 602 and 604. Therefore, the overlay 110 may be said to be aligned to the interdigitated conductive layer 104, so that when the region 602 is energized or powered, a corresponding overlay region is illuminated, and when the region 604 is energized or powered, a different corresponding overlay region is illuminated. Where the overlay 110 is not present, but where graphics are inkjet-printed directly on the transparent substrate 102, the transparent substrate 102 may alternatively be said to be divided into regions corresponding to the regions 602 and 604 of the interdigitated conductive layer 104.

It is noted that the optional protective layer 117, where present, may be applied to the EL panel 100 vis-à-vis the electrical connects 702A, 702B, 704A, and 704B in one of two ways. First, the electrical connects 702A, 702B, 704A, and 704B may be attached to, the interdigitated conductive layer 104, and then the protective layer 117 applied thereover. Second, the protective layer 117 may be initially applied to the interdigitated conductive layer 104, and then-the protective layer 117 cut or pierced to partially expose the regions 602 and 604 so that the electrical connects 702A, 702B, 704A, and 704B may be appropriately attached to the conductive regions 602 and 604 where exposed.

In one embodiment, the front conductor 103 may be transparent and substantially clear. In another embodiment, however, the front conductor 103 may be partially transparent, or translucent, and may be in color or in full-color. In this latter embodiment, for instance, the front conductor 103 may be formed by inkjet-printing conductive ink on the transparent substrate 102 in accordance with a desired image. The desired image may have regions that correspond to the combined anode-and-cathode regions 602 and 604. Thus, when the region 602 is energized, a corresponding region of the front conductor 103 is illuminated, and when the region 604 is energized, a different corresponding region of the front conductor 103 is illuminated. These regions of the front conductor 103 may be electrically isolated from one another, or may not be electrically isolated from one another.

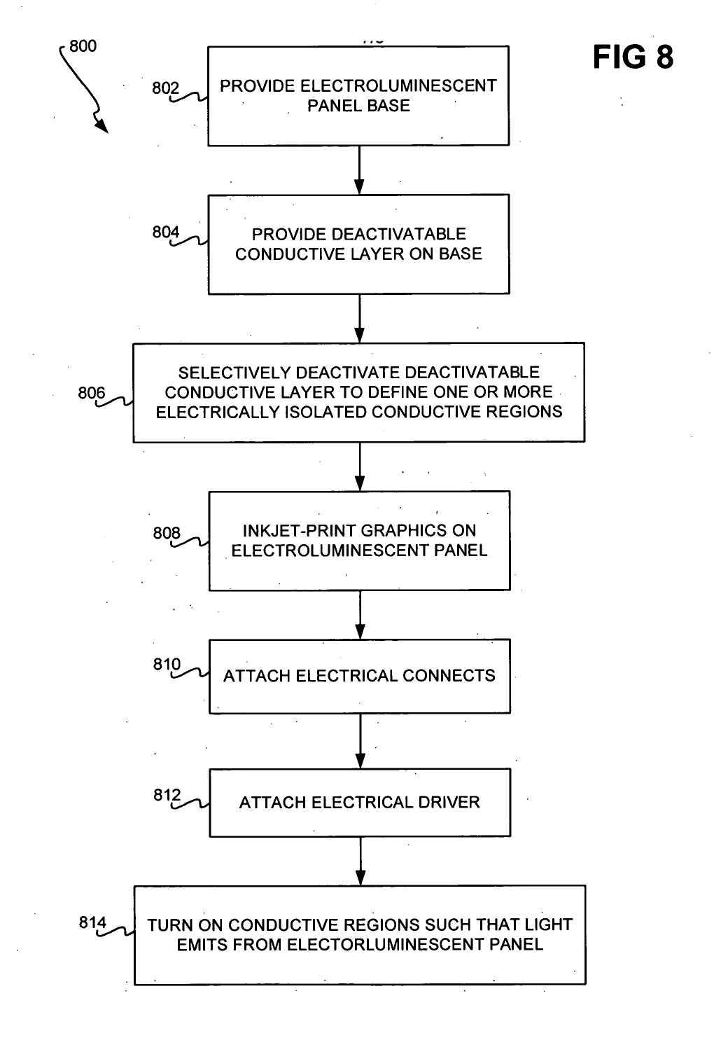

In another embodiment, the front conductor 103 may be implemented as the deactivatable conductive layer 116, such as an optical beam-deactivatable conductive layer as has been described, or as an activatable conductive layer, such as an optical beam-activatable conductive layer as has been described. In either instance, the front conductor 103 may be divided into electrically isolated regions that correspond to the combined anode-and-cathode regions 602 and 604 of the interdigitated conductive layer 104. Thus, when the region 602 is energized, a corresponding region of the front conductor 103 is illuminated, and when the region 604 is energized, a different corresponding region of the front conductor 103 is illuminated. The front conductor 103 in this embodiment may still be transparent. Furthermore, both the front conductor 103 and the conductive layer 116 may in one embodiment be a deactivatable or activatable patterned layer. FIG. 8 shows a method 800 that can be performed in relation to the EL panel 100 of FIGS. 1, 2, 3, and/or 5, according to an embodiment of the invention. The partial EL panel base 112 of FIG. 1 is first provided (802), and that includes at least the transparent substrate 102, the conductor/layer 103/104, the electroluminescent layer 106, and the dielectric layer 108. Thus, the partial EL panel base 112 may include the transparent front conductor 103 or the interdigitated conductive layer 104.

The deactivatable conductive layer 116 is then provided on the partial EL panel base 112 (804), and the layer 116 is selectively deactivated to define one or more electrically isolated conductive regions 118 (806). For instance, as has been described, an optical beam may be selectively emitted on the deactivatable conductive layer 116 to define the regions 118, where the optical beam has a wavelength to which the layer 116 is sensitive. Graphics may in one embodiment further be inkjet-printed on the EL panel 100 (808).

Electrical connects are then attached (810). In the embodiment where the EL panel 100 includes the transparent front conductor 103, an electrical connect is attached to each of the conductive regions 118, as well as to the front conductor 103 itself, as in FIG. 3. In the embodiment where the EL panel 100 includes the interdigitated conductive layer 104, an electrical connect is attached to the anode conductive region of the layer 104 and to the cathode conductive region of the layer 104, as in FIG. 5. An electrical driver is then attached to the other end of the electrical connects (812). Finally, the conductive regions 118 are turned on such that light emits from the EL panel 100 (814). For instance, in the embodiment where the EL panel 100 includes the transparent front conductor 103, turning on the conductive regions 118 means independently and selectively applying a voltage between the conductive regions 118 and the transparent front conductor 103, where the regions 118 each act as one electrode and the conductor 104 acts as another electrode. In the embodiment where the EL panel 100 includes the interdigitated conductive layer 104, turning on the conductive regions 118 means applying a voltage between the anode region and the cathode region of the layer 104, such that an electrical path is formed between the anode region of the layer 104, the conductive regions 118, and the cathode region of the layer 104. In this embodiment, the conductive regions 118 electrically bridge the anode and cathode regions of the layer 104 to form a capacitor between the anode and the cathode regions.

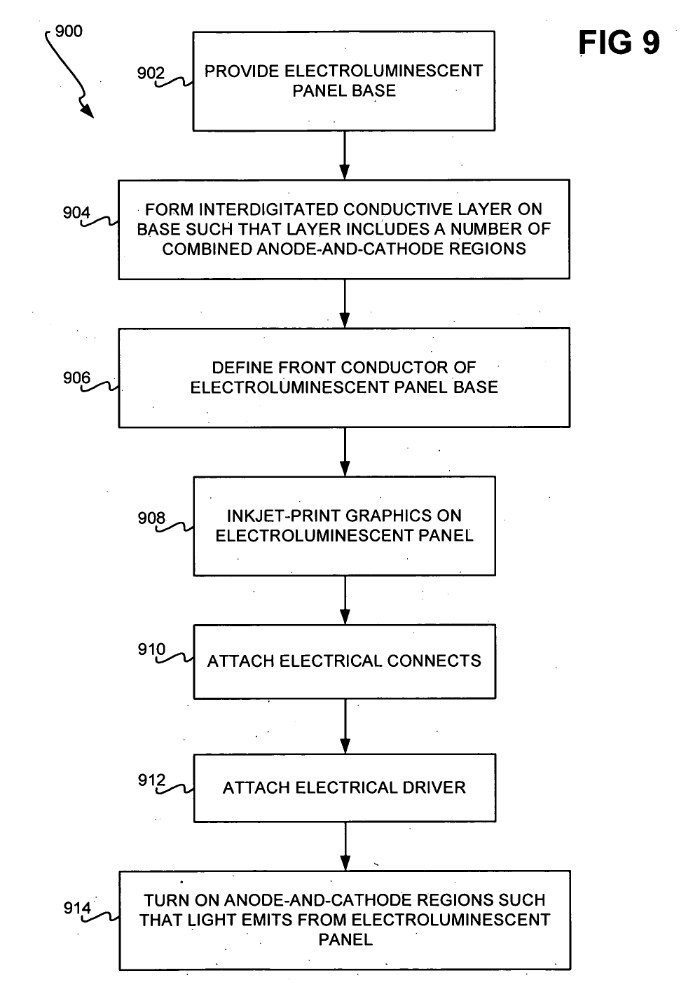

FIG. 9 shows a method 900 that can be performed in relation to the EL panel 100 of FIG. 7, according to an embodiment of the invention. The partial EL panel base 112 of FIG. 7 is first provided (902), and that includes at least the transparent substrate 102, the front conductor 103, the electroluminescent layer 106, and the dielectric layer 108. The interdigitated conductive layer 104 is then formed on the partial EL panel base 112 (904), such that the layer 104 includes a number of combined anode-and-cathode regions 602. For instance, the interdigitated conductive layer 104 may initially be a deactivatable conductive layer that is selectively deactivated to define the regions 602, or the layer 104 may initially be an activatable conductive layer that is selectively activated to define the regions 602.

The front conductor 103 of the EL panel base 112 may be defined in one embodiment (906). Defining the front conductor 103 can, for instance, include selectively deactivating the front conductor 103 where it is a deactivatable conductive layer, or selectively activating the front conductor 103 where it is an activatable conductive layer. Graphics may in one embodiment further be inkjet-printed on the EL panel 100 (908).

Electrical connects are then attached (910). Electrical connects are attached to each anode region and each cathode region of each of the combined anode-and-cathode regions 602, as has been described in relation to FIG. 7. An electrical driver is attached to the other end of the electrical connects (912). The anode-and-cathode regions 602 are then turned on such that light emits from the EL panel 100 (914). For instance, a voltage between the anode region and the cathode region of each of the anode-and-cathode regions 602 may be selectively and independently applied, to cause light to emit from a corresponding region of the EL panel 100 itself. Thus, the front conductor 103 in such instance acts as a bridge conductor for each of the anode-and-cathode regions 602, electrically bridging the anode region of each anode-and-cathode region to the cathode region of the anode-and-cathode region in question.

It is noted that, although specific embodiments have been illustrated and described herein, it will be appreciated by those of ordinary skill in the art that any arrangement is calculated to achieve the same purpose may be substituted for the specific embodiments shown. As just one example, whereas some embodiments of the invention have been substantially described in relation to defining rear electrode regions of an EL panel, other embodiments of the invention may be implemented in relation to defining other electrode regions, such as front electrode regions. This application is thus intended to cover any adaptations or variations of the present invention. Therefore, it is manifestly intended that this invention be limited only by the claims and equivalents thereof.

We claim:

1. An electroluminescent panel comprising:
a partial electroluminescent panel base; and,
a deactivatable conductive layer next to the partial electroluminescent panel base and selectively deactivated to define one or more electrically isolated conductive regions within the deactivatable conductive layer.

2. The electroluminescent panel of claim 1, wherein the conductive regions are capable of being independently and selectively powered, such that light emits from corresponding regions of the electroluminescent panel.

3. The electroluminescent panel of claim 1, wherein the one or more electrically isolated conductive regions comprise a plurality of conductive regions.

4. The electroluminescent panel of claim 1, wherein the deactivatable conductive layer is nonconductive where deactivated and otherwise is conductive.

5. The electroluminescent panel of claim 1, wherein the deactivatable conductive layer comprises an optical beam-deactivated conductive layer, such that the layer becomes nonconductive where exposed to an optical beam having a wavelength to which the layer is sensitive.

6. The electroluminescent panel of claim 1, wherein the deactivatable conductive layer comprises a conductive polymer composite, an antenna material, and carbon black.

7. The electroluminescent panel of claim 1, wherein the electrically isolated conductive regions-are rear electrode regions, and the partial electroluminescent panel base comprises a transparent front conductor, such that a corresponding capacitor is formed between each rear electrode region and the transparent front conductor.

8. The electroluminescent panel of claim 1, wherein graphics are inkjet-printed onto the partial electroluminescent panel base.

9. The electroluminescent panel of claim 1, wherein the partial electroluminescent panel base comprises a conductive layer defining both an anode and a cathode electrically isolated from one another within the conductive layer, the electrically isolated conductive regions electrically bridging the anode and the cathode.

10. The electroluminescent panel of claim 9, wherein application of power between the anode and the cathode results in light to emit from regions of the electroluminescent panel corresponding to the conductive regions.

11. The electroluminescent panel of claim 9, wherein the conductive layer is unpatterned.

12. The electroluminescent panel of claim 9, wherein the conductive layer is patterned to define one or more combined anode-and-cathode regions, each anode-and-cathode region having an anode and a cathode.

13. The electroluminescent panel of claim 9, wherein the conductive layer is transparent.

14. An electroluminescent panel comprising:
a partial electroluminescent panel base; and,
a conductive layer patterned to define a plurality of combined anode-and-cathode regions each having an anode and a cathode electrically isolated from one another within the conductive layer.

15. The electroluminescent panel of claim 14, wherein the anode-and-cathode regions are capable of being independently and selectively powered, such that light emits from corresponding regions of the electroluminescent panel.

16. The electroluminescent panel of claim 14, wherein the conductive layer comprises a deactivatable conductive layer that is selectively deactivated to define the anode-and-cathode regions.

17. The electroluminescent panel of claim 16, wherein the deactivatable conductive layer comprises an optical beam-deactivated conductive layer, such that the layer becomes nonconductive where exposed to an optical beam having a wavelength to which the layer is sensitive.

18. The electroluminescent panel of claim 14, wherein the conductive layer comprises an activatable conductive layer that is selectively activated to define the anode-and-cathode regions.

19. The electroluminescent panel of claim 18, wherein the activatable conductive layer comprises an optical beam-activated conductive layer, such that the layer becomes conductive where exposed to an optical beam having a wavelength to which the layer is sensitive.

20. The electroluminescent panel of claim 14, wherein the partial electroluminescent panel base comprises a bridge conductor to electrically bridge the anode and the cathode of each anode-and-cathode region.

21. An electroluminescent panel comprising:
a transparent conductor;
an electroluminescent layer next to the transparent conductor;
a dielectric next to the electroluminescent layer; and,
means for forming one or more capacitors with the transparent conductor, the electroluminescent layer, and the dielectric via selective deactivation using an optical beam.

22. An electroluminescent panel comprising:
a transparent conductor;
an electroluminescent layer next to the transparent conductor;
a dielectric next to the electroluminescent layer; and,
means for forming one or more capacitors with the transparent conductor, the electroluminescent layer, and the dielectric via a corresponding one or more combined anode-and-cathode regions each having an anode and a cathode electrically isolated from one another.

23. A method comprising:
providing an electroluminescent panel; and,
selectively deactivating a deactivatable conductive layer on the electroluminescent panel to define one or more electrically isolated conductive regions within the deactivatable conductive layer.

24. The method of claim 23, wherein selectively deactivating the deactivatable conductive layer of the electroluminescent panel comprises selectively emitting an optical beam on the deactivatable conductive layer.

25. The method of claim 23, wherein the electroluminescent panel further has a front transparent conductor to correspondingly form one or more capacitors between the conductive regions and the front transparent conductor, such that the conductive regions are capable of being independently and selectively powered to emit light from corresponding regions of the electroluminescent panel.

26. The method of claim 23, wherein the electroluminescent panel further has an conductive layer having both an anode and a cathode electrically isolated from one another within the conductive layer, the electrically isolated conductive regions electrically bridging the anode and the cathode to form a capacitor between the anode and the cathode.

27. A method comprising:
providing an electroluminescent panel base; and,
forming a conductive layer on the electroluminescent panel base such that the conductive layer includes a plurality of combined anode-and-cathode regions, each conductive layer having an anode and a cathode.

28. The method of claim 27, wherein forming the conductive layer such that the conductive layer includes the combined anode-and-cathode regions comprises selectively deactivating a deactivatable conductive layer to define the combined anode-and-cathode regions, such that the deactivatable conductive layer becomes nonconductive where deactivated.

29. The method of claim 27, forming the conductive layer such that the conductive layer includes the combined anode-and-cathode regions comprises selectively activating an activatable conductive layer to define the combined anode-and-cathode regions, such that the activatable conductive layer becomes conductive where activated.

30. The method of claim 27, wherein the electroluminescent panel further has a bridge conductor to electrically bridge the anode and the cathode of each combined anode-and-cathode region.
